(19) United States
(12) Patent Application Publication
(10) Pub. No.: US 2012/0138137 A1
(43) Pub. Date: Jun. 7, 2012

(54) Solar Cell

(75) Inventors: Bing-Cyun Chen, New Taipei City (TW); Wei-Chih Hsu, Hsinchu County (TW); Wei-Lun Chang, Yilan County (TW); Chen-Hsun Du, Taipei City (TW)

(73) Assignee: INDUSTRIAL TECHNOLOGY RESEARCH INSTITUTE, Hsinchu (TW)

(21) Appl. No.: 13/230,771

(22) Filed: Sep. 12, 2011

(30) Foreign Application Priority Data
Dec. 7, 2010 (TW) TW099142534

(51) Int. Cl. H01L 31/0224

(52) U.S. Cl. 136/256

(57) ABSTRACT

The invention provides a solar cell which includes a solar cell, comprising: a first conductivity type semiconductor substrate, wherein the first conductivity type semiconductor substrate comprises a light receiving surface, a non-light receiving surface and a plurality of through holes extending from the light receiving surface to the non-light receiving surface; a second conductivity type semiconductor layer formed on the non-light receiving surface and extended into the first conductivity type semiconductor substrate, wherein the second conductivity type is opposite to the first conductivity type; a first electrode layer formed on the second conductivity type semiconductor layer; and a second electrode layer formed on the light receiving surface and extended to the non-light receiving surface by the through hole.

### CROSS REFERENCE TO RELATED APPLICATIONS

This Application claims priority of Taiwan Patent Application No. 099142534, filed on Dec. 7, 2010, the entirety of which is incorporated by reference herein.

### BACKGROUND OF THE INVENTION

1. Field of the Invention

The present invention relates to a solar cell, and in particular relates to a back contact solar cell.

2. Description of the Related Art

Development in the solar cell industry is driven by global environmental concerns and rising raw material prices.

Compared with conventional silicon solar cells, back-contact solar cells have several advantages. The first advantage is that back-contact cells have high conversion efficiencies due to reduced contact obscuration losses. The second advantage is that it is easy to assembly back-contact cells into electrical circuits, thus, implementation is cheap, because both polarity contacts are on a same surface.

During the fabrication of a metallization wrap through (MWT) back contact solar cell, paste is filled into a through hole for conductive purposes. Then, the paste and a light-receiving electrode are co-fired at a high temperature to attach the paste onto the substrate. However, during the co-firing process, the paste may pass through the sidewall of the through hole, and further through a pn junction. Therefore, shunt resistance (Rₛₕ) and filler factor (FF) of the back contact solar cell may be reduced.

Therefore, there is a need to develop a solar cell having better adhesion between the paste and the substrate, such that the shunt resistance (Rₛₕ) of the solar cell may not be reduced.

### BRIEF SUMMARY OF THE INVENTION

The invention provides a solar cell, comprising: a first conductivity type semiconductor substrate, wherein the first conductivity type semiconductor substrate comprises a light receiving surface, a non-light receiving surface and a plurality of through holes extending from the light receiving surface to the non-light receiving surface; a second conductivity type semiconductor layer formed on the non-light receiving surface and extended into the first conductivity type semiconductor substrate, wherein the second conductivity type is opposite to the first conductivity type; a first electrode layer formed on the second conductivity type semiconductor layer; and a second electrode layer formed on the light receiving surface and extended to the non-light receiving surface by the through hole.

A detailed description is given in the following embodiments with reference to the accompanying drawings.

### BRIEF DESCRIPTION OF THE DRAWING

For a more complete understanding of the present invention, and the advantages thereof, reference is now made to the following descriptions taken in conjunction with the accompanying drawings, in which:

FIGS. 1A-1G show cross-sectional schematic representations of various stages of fabricating a solar cell in accordance with an embodiment of the invention; and

FIG. 2 shows a cross-sectional schematic representation of a solar cell in accordance with another embodiment of the invention;

FIG. 3 shows the relationship between open-circuit voltage (V_{oc}) and short-circuit current (J_{sc}) of the Example and Comparative Example.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

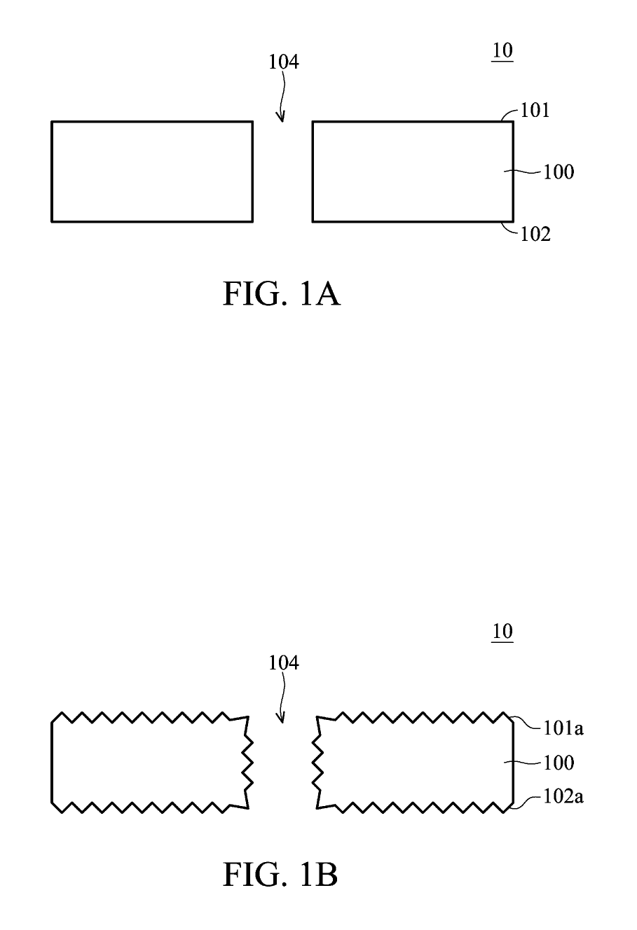

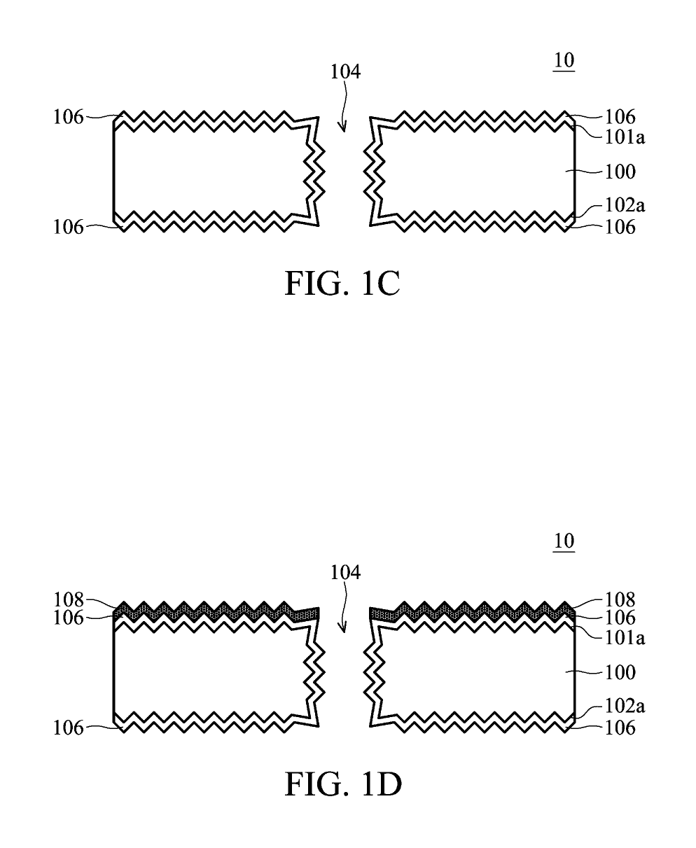

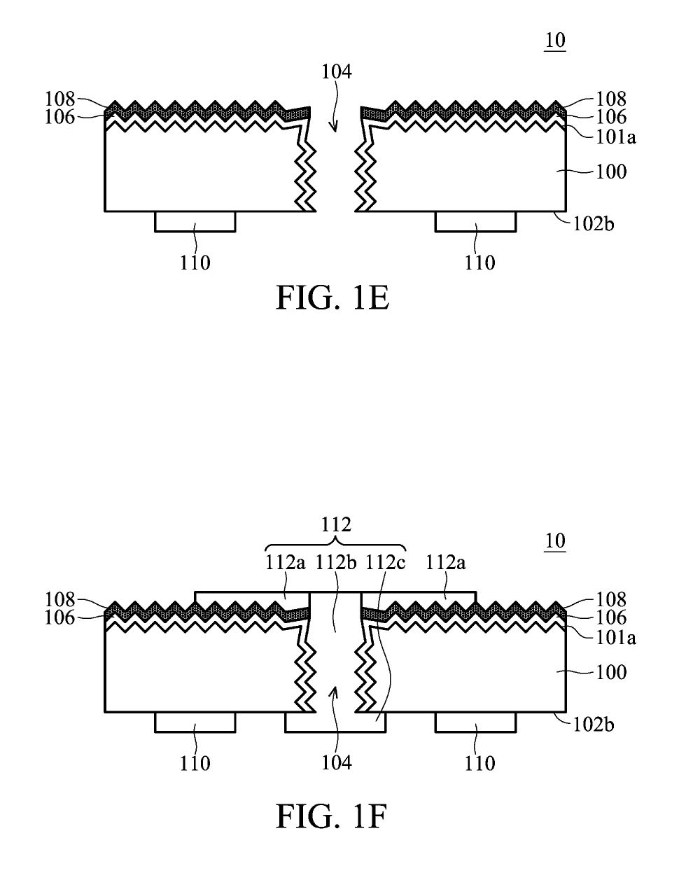

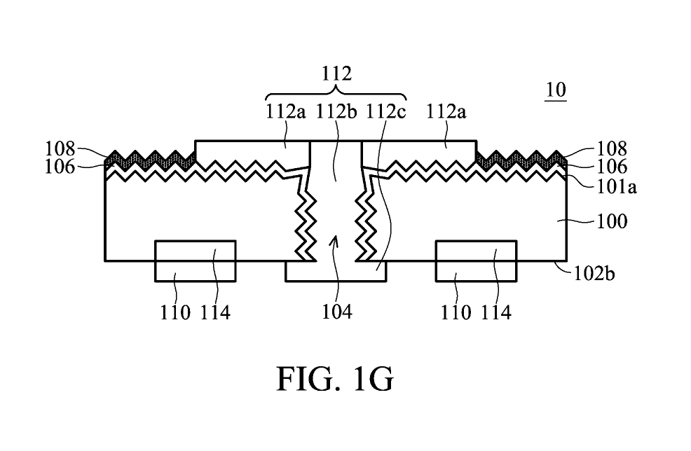

The invention provides a solar cell 10 having improved adhesion between a paste and a substrate, such that shunt resistance (Rₛₕ) of the solar cell may not been reduced. FIGS. 1A-1G show cross-sectional schematic representations of various stages of fabricating a solar cell in accordance with an embodiment of the invention.

Firstly, referring to FIG. 1A, a first conductivity type semiconductor substrate 100 is provided and comprises a light receiving surface 101, a non-light receiving surface 102 and a plurality of through holes 104 extending from the light receiving surface 101 to the non-light receiving surface 102. The light receiving surface 101 is used to absorb the light to convert the light energy into the electrical energy. The through holes 104 are used so that a paste may be filled thereinto. The light receiving surface 101 is electrically connected to the non-light receiving surface 102 by the through holes 104. The through holes 104 have a diameter of about 25-125 μm and they are fabricated by a laser drilling method, a mechanical drilling method or water jet machining.

Referring to FIG. 1B, a base etching step is conducted to form a textured light receiving surface 101a and a textured non-light receiving surface 102a. The base etching step is used to eliminate damage produced by previous steps (e.g. the substrate 100 may be damaged by the drilling methods). Additionally, the textured surfaces 101a, 102a are formed to improve the anti-reflective effect of the first conductivity type semiconductor substrate 100. In one embodiment, the first conductivity type semiconductor substrate 100 is soaked into a 10% sodium hydroxide (NaOH) solution or a potassium hydroxide (KOH) solution to conduct the base etching step.

Referring to FIG. 1C, a first conductivity type semiconductor layer 106 is formed on the textured light receiving surface 101a, the sidewalls of the through holes 104 and the textured non-light receiving surface 102a by doping of a first conductivity type dopant. The first conductivity type may be an N type or P type, wherein the N type is formed by doping an n dopant such as phosphorus (P), arsenic (As), antimony (Tb), etc., and a P type is formed by doping a p dopant such as boron (B), aluminum (Al), germanium (Ge), indium (In), etc. Note that a first conductivity type semiconductor layer 106 which is doped heavier than first conductivity type semiconductor substrate 100 formed on the light receiving surface 101 and the sidewalls of the through holes 104.

In one embodiment, when the first conductivity type is the N type, an N⁺ layer 106 is formed on the textured light receiving surface 101a, the sidewalls of the through holes 104 and the textured non-light receiving surface 102a by doping of POCl₃. In another embodiment, when the first conductivity type is the P type, a p⁺ layer 106 is formed on the textured light receiving surface 101a, the sidewalls of the through holes 104 and the textured non-light receiving surface 102a by doping of BBr₃.

Referring to FIG. 1D, an anti-reflective coating (ARC) 108 is formed on the first conductivity type semiconductor layer 106. The anti-reflective coating (ARC) 108 comprises dielectric materials, such as SiN, SiO₂, TiO₂ or Ta₂O₅. The anti-reflective coating (ARC) 108 is formed by plasma enhanced chemical vapor deposition (PECVD), low pressure chemical vapor deposition (LPCVD), ink jet printing or coating method. In one embodiment, formation of the first conductivity type semiconductor layer 106 may be omitted, and the anti-reflective coating (ARC) 108 is directly formed on the textured light receiving surface 101a.

Referring to FIG. 1E, the textured non-light receiving surface 102a is etched by a base etching process, and then it is polished by a polishing process, wherein the base solution is such as sodium hydroxide (NaOH) solution or potassium hydroxide (KOH) solution. After the polishing process, a planar non-light receiving surface 102b is obtained. Next, a first electrode layer 110 is formed on the planar non-light receiving surface 102b. The first electrode layer 110 is formed by screen printing, ink jet printing, electroplating or electroless plating.

FIG. 1F shows formation of a second electrode layer 112. The second electrode layer 112 is divided into three regions, wherein a first region 112a of the second electrode layer 112 is formed on the anti-reflective coating 108, a second region 112b of the second electrode layer 112 is formed in the through holes 104 and a third region 112c of the second electrode layer 112 is formed on the planar non-light receiving surface 102b.

The first region 112a, the second region 112b and the third region 112c of the second electrode layer 112 is formed by a method which is the same as that of the first electrode layer 110, and thus, the detailed description thereof is omitted here. Alternatively, the second region 112b and the third region 112c may be formed in another method. For example, the second region 112b and the third region 112c of the second electrode layer 112 are formed by filling a paste into the through holes 104 by a screen printing method. Then, the paste and the first region 112a of the second electrode layer 112 are co-fused together by a co-firing step at a high temperature. The temperature is conducted at about 700° C.-850° C., and preferably 730° C.-800° C., and more preferably 750° C.-770° C.

In one embodiment, the first region 112a of the second electrode layer 112 is made of a silver or silver alloy, while the second region 112b and the third region 112c of the second electrode layer 112 are made of a paste containing silver. In addition to silver, the paste further comprises glass and organic solvent, and the silver is used as a conductive material, the glass is used as a binder and the organic solvent is helpful for the screen printing method.

FIG. 1G shows a cross-sectional representation of the solar cell of the invention after the co-firing step. After the co-firing step, the paste in the through holes 104 and the second electrode layer 112a on the textured light receiving surface 101a are co-fused to form the second electrode layer 112. Furthermore, the first conductivity type semiconductor layer 106 formed on the textured light receiving surface 101a may pass through the anti-reflective coating 108, and thus, the first conductivity type semiconductor layer 106 is electrically connected to the second electrode layer 112. Additionally, after the co-firing step, a second conductivity type semiconductor layer 114 is formed on the non-light receiving surface 102b of the semiconductor substrate 100, and the second conductivity type is opposite to the first conductivity type, and the second conductivity type semiconductor layer 114 is extended into the semiconductor substrate 100 and next to the first electrode layer 110. Note that the second conductivity type semiconductor layer 114 does not contact with the second electrode layer 112.

In one embodiment, when the first conductivity type is the N type and the second conductivity type is the P type, the semiconductor substrate is an N type, the first electrode layer 110 is aluminum or aluminum alloy and the second electrode layer 112 is silver or silver alloy.

In another embodiment, when the first conductivity type is the P type and the second conductivity type is the N type, the semiconductor substrate is a P type, the first electrode layer 110 is silver or silver alloy and the second electrode layer 112 is aluminum or aluminum alloy.

Referring to FIG. 1G, the area of the first electrode layer 110 is equal to that of the second conductivity type semiconductor layer 114. In another embodiment, the area of the first electrode layer 110 is smaller than that of the second conductivity type semiconductor layer 114.

In one embodiment, when the first electrode layer 110 is aluminum which is a p type dopant, a P⁺ layer 114 formed in the semiconductor substrate 100 is obtained by diffusing the aluminum into the semiconductor substrate 100 after the co-firing step.

Note that good adhesion between the paste of the third region 112c of the second electrode layer 112 and the semiconductor substrate 100 is obtained by the co-firing step to facilitate a following module packaging process.

Moreover, the second conductivity type semiconductor layer 114 may be formed by a chemical vapor deposition (CVD) method. For example, a P⁺ layer 114 is formed by a plasma enhanced chemical vapor deposition (PECVD) method by introducing SiH₄ and B₂H₆ into a reaction chamber.

In yet another embodiment, an N⁺ layer 114 is formed by a plasma enhanced chemical vapor deposition (PECVD) method by introducing SiH₄ and PH₃ into a reaction chamber.

Note that a pn junction is formed between the first conductivity type semiconductor substrate 100 and the second conductivity type semiconductor layer 114. In other words, the pn junction is formed on the planar non-light receiving surface 102b, rather than light receiving surface. Therefore, the paste does not pass through the pn junction, and the leaking current of the solar cell 10 of the invention is reduced and the shunt resistance (Rₛₕ) is improved.

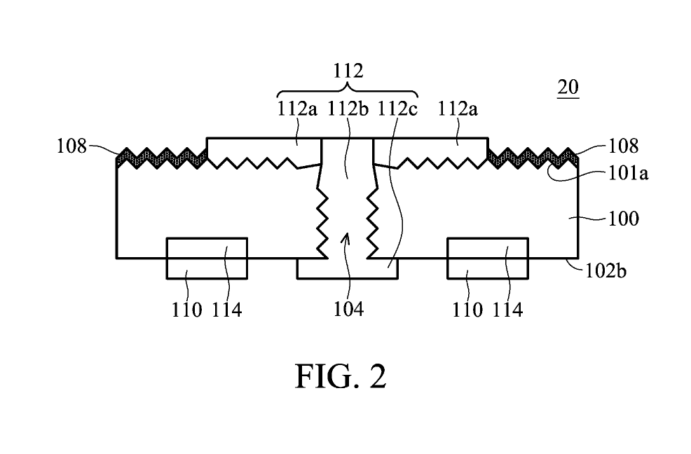

FIG. 2 shows another embodiment of the solar cell 20 of the invention. The difference between FIG. 2 and FIG. 1G is that no first conductivity type semiconductor layer 106 is formed in FIG. 2, and thus the fabricating method of the FIG. 2 is simper than that of FIG. 1. The other devices and their fabrication methods of the FIG. 2 are the same as FIG. 1A-1G, and thus, detailed description thereof is omitted here.

In the second embodiment, the pn junction is formed on the planar non-light receiving surface 102b, rather than the light receiving surface. Thus, the paste does not pass through the pn junction, such that the leaking current of the solar cell 20 of the invention is reduced and the shunt resistance (Rₛₕ) is improved.

Therefore, the invention provides solar cells 10, 20 with good adhesion between the paste of the through holes and the semiconductor substrate 100. The shunt resistance (Rₛₕ) of the solar cells 10, 20 is not reduced and the leaking current of the solar cells 10, 20 is improved.

### EXAMPLE

### Example

Referring to FIG. 1G, the solar cell of the Example comprises an N type semiconductor substrate 100, an N type semiconductor layer 106 formed on a textured light receiving surface 101a, and a P type semiconductor layer 114 formed on a planar non-light receiving surface 102b and extending into the N type semiconductor substrate 100. The first electrode layer 110 is aluminum, the second electrode layer 112 is silver, and the PN junction is formed on the planar non-light receiving surface 102b.

### Comparative Example

The difference between the Example and Comparative Example is that the P-type substrate is used in the Comparative Example, and thus, the PN junction of the Comparative Example is located on the light receiving surface.

Table 1 shows the open-circuit voltage (V_{oc}), short-circuit current (J_{sc}), fill factor, power conversion efficiency and shunt resistance (Rsh) of the Example and Comparative Example. The shunt resistance (Rsh) identifies the leaking current of the solar cell, wherein the greater the shunt resistance, the smaller the leaking current. As shown in Table 1, the shunt resistance (Rsh) of the Example is 9.496 Ohm and the shunt resistance (Rsh) of the Comparative Example is 3.288 Ohm. Thus, the leaking current of the solar cell of the invention is improved when compared to the Comparative Example.

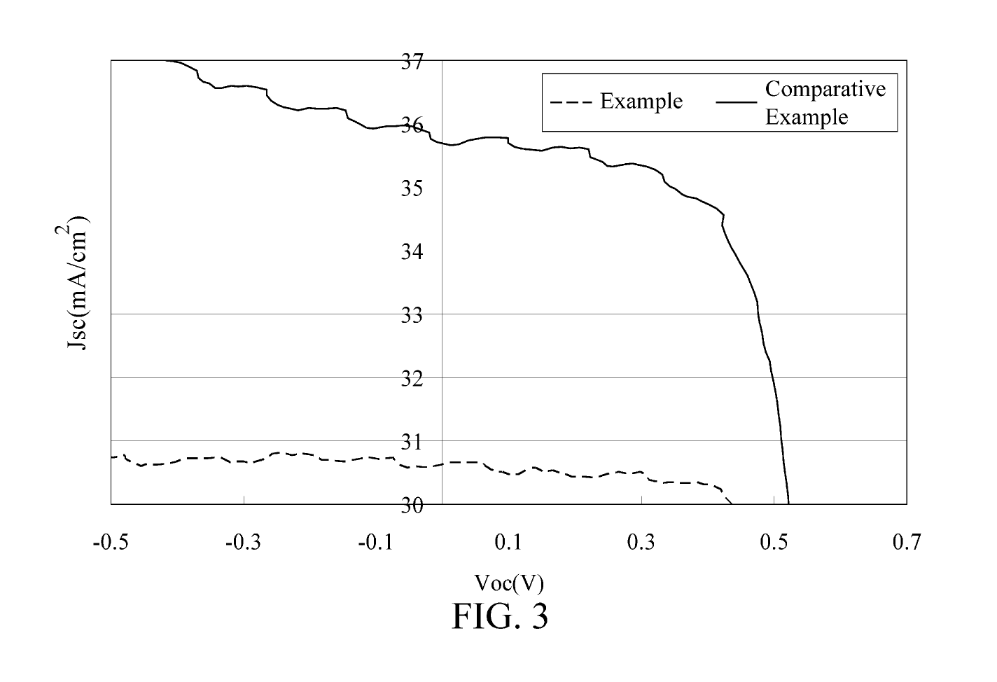

FIG. 3 shows a relationship between open-circuit voltage (V_{oc}) and short-circuit current (J_{sc}) of the Example and Comparative Example. As shown in FIG. 3, as the open-circuit voltage (V_{oc}) is 0 V, the slope of the leaking current of the Example is smaller than that of the Comparative Example. Therefore, the leaking current of the Example is less than that of the Comparative Example.

TABLE 1

| | V_{oc} | J_{sc} | Fill | power conversion | |
|---|---|---|---|---|---|
| | (V) | (mA/cm2) | Factor | efficiency (%) | Rₛₕ(Ω) |
| Example | 0.614 | 30.36 | 75.53 | 14.09 | 9.496 |
| Comparative | 0.610 | 35.70 | 65.76 | 14.31 | 3.288 |
| Example | | | | | |

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell, comprising:
a first conductivity type semiconductor substrate, wherein the first conductivity type semiconductor substrate comprises a light receiving surface, a non-light receiving surface and a plurality of through holes extending from the light receiving surface to the non-light receiving surface;
a second conductivity type semiconductor layer formed on a part of the non-light receiving surface and extended into the first conductivity type semiconductor substrate, wherein the second conductivity type is opposite to the first conductivity type;
a first electrode layer formed on the second conductivity type semiconductor layer; and
a second electrode layer formed on the light receiving surface and extended to the non-light receiving surface by the through hole, and the second electrode layer does not contact with the second conductivity type semiconductor layer.

2. The solar cell as claimed in claim 1, further comprising an anti-reflective coating (ARC) formed on the light receiving surface.

3. The solar cell as claimed in claim 2, wherein the anti-reflective coating comprises dielectric materials.

4. The solar cell as claimed in claim 2, wherein the anti-reflective coating comprises SiN, SiO₂, TiO₂ or Ta₂O₅.

5. The solar cell as claimed in claim 1, further comprising a first conductivity type semiconductor layer which is doped heavier than the first conductivity type semiconductor substrate formed on the light receiving surface and the sidewalls of the through holes.

6. The solar cell as claimed in claim 5, further comprising an anti-reflective coating formed on the first conductivity type semiconductor layer.

7. The solar cell as claimed in claim 1, wherein the second electrode layer comprises:
a first region formed on the anti-reflective coating;
a second region formed in the through holes; and
a third region formed on the non-light receiving surface.

8. The solar cell as claimed in claim 1, wherein the first conductivity type is N-type, and the second conductivity type is P-type.

9. The solar cell as claimed in claim 1, wherein first conductivity type is P-type, and the second conductivity type is N-type.

10. The solar cell as claimed in claim 1, wherein the first electrode layer and the second electrode layer respectively comprises aluminum, silver or combinations thereof.

11. The solar cell as claimed in claim 1, wherein the area of the first electrode layer is smaller than or equal to that of the second conductivity type semiconductor layer.

12. The solar cell as claimed in claim 1, wherein the second conductivity type semiconductor layer does not contact with the second electrode layer.
